(19) United States
(12) Patent Application Publication
(10) Pub. No.: US 2025/0125278 A1
(43) Pub. Date: Apr. 17, 2025

(54) Method for Ensuring the Integrity of Semiconductor Devices From Wafer Fabrication Through Packaging

(71) Applicant: Tracer Validation Inc., Ogden, UT (US)

(72) Inventors: Matt Bellis, Lexington, KY (US); C. Davis Woodbury, Roy, UT (US)

(21) Appl. No.: 18/912,994

(22) Filed: Oct. 11, 2024

Related U.S. Application Data
(60) Provisional application No. 63/589,903, filed on Oct. 12, 2023.
(60) Provisional application No. 63/662,244, filed on Jun. 20, 2024.

(51) Int. Cl. H01L 23/544; H01L 21/66; H01L 21/67; H01L 23/00

(52) U.S. Cl. CPC H01L 23/544; H01L 21/67294; H01L 23/573; H01L 22/20; H01L 2223/54433; H01L 2223/5446; H01L 2223/5448

(57) ABSTRACT

Secure marks for semiconductor devices and methods for marking semiconductor devices are disclosed. The secure marks and methods for marking may be incorporated at various stages in the lifecycle of a semiconductor device, including the design, mask fabrication, wafer fabrication, singulation, and packaging processes.

### CROSS-REFERENCE TO RELATED APPLICATIONS

This application claims priority to U.S. Provisional Application No. 63/589,903 filed Oct. 12, 2023, and U.S. Provisional Application No. 63/662,244 filed Jun. 20, 2024, each titled “Method for Ensuring the Integrity of Semiconductor Devices from Wafer Fabrication through Packaging,” and which are incorporated by reference herein in their entirety.

### FIELD OF THE TECHNOLOGY

This technology is related generally to the field of semiconductor device security. More specifically, this technology relates to the challenges of tracking a semiconductor device as the device is manufactured and deployed. This may include all the various stages of the lifecycle of a semiconductor device, including, by way of example, wafer processing, packaging, and implementation of the semiconductor device into a final product. For example, the technology described herein allows for the tracking of a semiconductor device deployed in a mobile phone from the wafer processing stage all the way through deployment of the semiconductor device in the mobile phone and continuing up to disposal or recovery of the semiconductor device at the end of the life of the mobile phone.

### BACKGROUND OF THE TECHNOLOGY AND RELATED ART

Tracking semiconductor devices across the various stages of the lifecycle of a semiconductor device presents several challenges. First, the design, fabrication, and use of semiconductor devices generally involve many suppliers and several facilities. For example, the delivery of an advanced graphics processing unit (GPU) to an end-user could involve at least the following steps:
1. Specification of the GPU requirements by the company that ultimately owns the intellectual property of the GPU and is responsible for sales of the GPU in the market;
2. Transfer of the GPU requirements to a design company where the design of the GPU occurs;
3. Transfer of the GPU design in the form of digital files comprising at least a set of semiconductor processing masks to a company that specializes in the fabrication of semiconductor processing masks;
4. Transfer of the semiconductor processing masks to a semiconductor foundry for wafer processing and device fabrication;
5. Transfer of the processed semiconductor wafer to a company that specializes in semiconductor device packaging;
6. Transfer of the packaged semiconductor devices, the GPU in this example, to a testing facility to test and prepare the components for shipment;
7. Transfer of the final semiconductor devices, the GPU in this example, to a channel partner for sales and distribution; and
8. Transfer to a company that will integrate the final semiconductor devices, e.g., the GPU, into a product, for example a graphics card, and sell the product, e.g., graphics card, to the end-user.

Second, several of these steps are destructive in nature. For example, markings on a wafer can be destroyed during the dicing process. As another example, markings on a die can be destroyed or hidden after packaging the die. Aspects of the technology disclosed herein address these challenges.

### BRIEF DESCRIPTION OF THE DRAWINGS

Various aspects of the present technology will become more fully apparent from the following description and appended claims, taken in conjunction with the accompanying drawings. Understanding that these drawings merely depict exemplary aspects of the present technology, they are therefore not to be considered limiting of its scope. It will be readily appreciated that the components of the present technology, as generally described and illustrated in the figures herein, could be arranged and designed in a wide variety of different configurations. Nonetheless, the technology will be described and explained with additional specificity and detail through the use of the accompanying drawings in which:

FIG. 1 illustrates a process from circuit schematic to mask layout to semiconductor fabrication in accordance with one aspect of the technology;

FIG. 2 illustrates the fabrication process for an Extreme Ultraviolet (EUV) mask in accordance with one aspect of the technology;

FIG. 3 illustrates steps fabricating a semiconductor chip, including wafer processing, in accordance with one aspect of the technology;

FIG. 4 illustrates wafer dicing in accordance with one aspect of the technology;

FIG. 5 illustrates wafer dicing in accordance with one aspect of the technology;

FIG. 6 illustrates how the intellectual property in developing a semiconductor chip (die) moves from concept, to fabrication, to an end user, according to one aspect of the technology;

FIG. 7 is a final product comprising multiple semiconductor devices according to one aspect of the technology;

FIG. 8 illustrates one or more secure marks in scribe lines according to one aspect of the technology;

FIG. 9 illustrates layers of die attach film (DAF) tape according to one aspect of the technology;

FIG. 10 illustrates an extrusion process according to one aspect of the technology;

FIG. 11 illustrates a random dispersion of particles in DAF tape according to the one aspect of the technology;

FIG. 12 illustrates a method for applying one or more secure marks throughout the packaging process according to one or more aspects of the technology;

FIG. 13 is a final product according to one or more aspects of the technology; and

FIG. 14 is illustrates a series of smart contracts connected to blockchain server to create a digital record according to one or more aspects of the technology.

### DETAILED DESCRIPTION

The following detailed description of exemplary aspects of the technology refers to the accompanying drawings, which form a part hereof and in which are shown, by way of illustration, exemplary aspects in which the technology may be practiced. While these exemplary aspects are described in sufficient detail to enable those skilled in the art to practice the technology, it should be understood that other aspects may be realized and that various changes to the technology may be made without departing from the spirit and scope of the present technology. Thus, the following more detailed description of the aspects of the present technology is not intended to limit the scope of the technology, as claimed, but is presented for purposes of illustration only and not limitation to describe the features and characteristics of the present technology and to sufficiently enable one skilled in the art to practice the technology. Accordingly, the scope of the present technology is to be defined solely by the appended claims.

As used in this specification and the appended claims, the singular forms “a,” “an” and “the” include plural referents unless the context clearly dictates otherwise. Thus, for example, reference to “a line” includes a plurality of such lines. In this disclosure, “comprises,” “comprising,” “containing” and “having” and the like can have the meaning ascribed to them in U.S. Patent law and can mean “includes,” “including,” and the like, and are generally interpreted to be open ended terms.

The terms “first,” “second,” “third,” “fourth,” and the like in the description and in the claims, if any, are used for distinguishing between similar elements and not necessarily for describing a particular sequential or chronological order. It is to be understood that any terms so used are interchangeable under appropriate circumstances such that the embodiments described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments described herein are, for example, capable of operation in other orientations than those illustrated or otherwise described herein. The term “coupled,” as used herein, is defined as directly or indirectly connected in any manner. Objects described herein as being “adjacent to” each other may be in physical contact with each other, in close proximity to each other, or in the same general region or area as each other, as appropriate for the context in which the phrase is used. Occurrences of the phrase “in one embodiment,” or “in one aspect,” herein do not necessarily all refer to the same embodiment or aspect.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint. Unless otherwise stated, use of the term “about” in accordance with a specific number or numerical range should also be understood to provide support for such numerical terms or range without the term “about”.

As used herein, the term “semiconductor device” means an electronic component that uses the electrical properties of semiconductor materials, including, for example, silicon, germanium, or compound semiconductors like gallium arsenide. Semiconductor devices include, but are not limited to, diodes, transistors, photovoltaic cells, thyristors, silicon-controlled rectifiers (SCRs), and integrated circuits (ICs) or chips.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Reference throughout this specification to “an example” means that a particular feature, structure, or characteristic described in connection with the example is included in at least one embodiment. Thus, appearances of the phrase “in an example” in various places throughout this specification are not necessarily all referring to the same embodiment.

The present technology describes methods for ensuring the integrity of semiconductor devices from wafer fabrication through downstream manufacturing, testing, distribution, and implementation. Some aspects of the development of semiconductor devices from initial design through wafer fabrication and dicing, die packaging, and semiconductor device distribution and integration into final products is provided below.

In one aspect of the technology, the design of a semiconductor device begins with defining the specifications and requirements of the semiconductor device, such as its functionality, performance characteristics, power requirements, and size constraints. In one aspect, this phase involves collaboration between engineers, designers, and stakeholders to establish clear objectives for the semiconductor device.

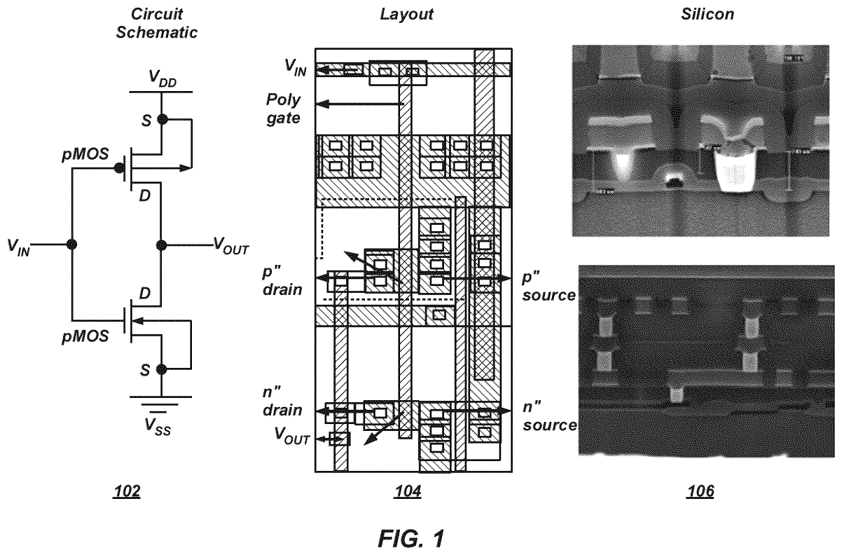

With reference to FIG. 1 generally, engineers using software tools, e.g., Electronic Design Automation (EDA) tools, to design the circuitry of the semiconductor device. This involves creating a schematic diagram 102 of the various electrical components and their connections. Simulation tools are then used to analyze the behavior of the circuit under different operating conditions, ensuring that the design meets the desired specifications.

Once the circuit design 102 is finalized, engineers proceed to layout design 104. This involves, among other things, arranging the components on the semiconductor substrate (often silicon). The layout design 104 is important for minimizing signal interference, optimizing performance, and ensuring manufacturability, for example.

Using the layout design 104 as a blueprint, engineers generate masks that define the patterns to be etched on the semiconductor substrate during the fabrication process. These masks are typically created using specialized software tools and are important for designing the geometries of the semiconductor device components. Fabrication of the circuit schematic 104 into silicon 106 can require multiple masks. For example, semiconductor devices with 30 to 40 masks are common.

Mask fabrication can be completed by specialized suppliers. The circuit schematic 102 or layout 104 is used by the mask fabricator, in conjunction with details regarding the fabrication process, to develop a specific set of masks for the semiconductor device. Each mask represents a specific step in the overall wafer fabrication process. The type of mask fabricated is also dependent upon the target manufacturing process. For example, in one aspect of the technology, a circuit schematic that is targeting a wafer processing node with a critical dimension that is at or below 7 nm may require an EUV (Extreme Ultra Violet) mask.

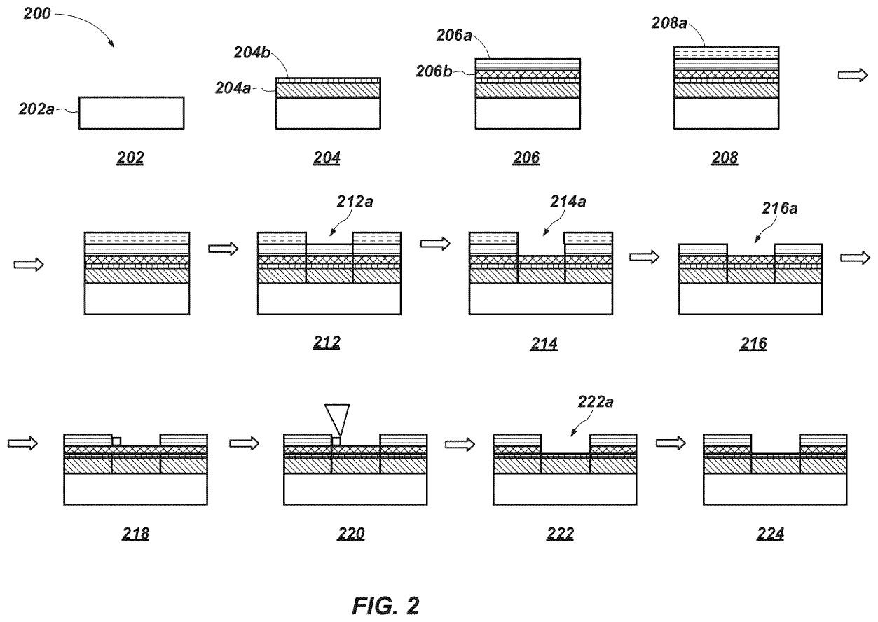

FIG. 2 shows a fabrication process 200 of an EUV mask, in accordance with one aspect of the technology. A first step of the fabrication process generally involves susbtrate preparation 202. The base material of an EUV mask is typically a highly polished low-thermal expansion glass (LTEM) substrate 202a, often made from materials like quartz or fused silica. The surface of the substrate 202a is polished to mimize defects that could distort the lithography process.

A second step of the fabrication process may involve multilayer deposition 204. EUV masks work with reflective optics because EUV light is absorbed by most materials. To refelect EUV light, a stack of Molybdenum/Silicon (Mo/Si) multilayers 204a is deposited on the substrate 202. Each Mo/Si layer is around 2-3 nm thick, and there are typically 40 to 50 layers, which serve as a Bragg reflector that reflects the EUV light.

A capping layer 204b may be deposited on the Mo/Si multilayer stack to protect it from environmental degredation, particularly oxidation. The capping layer 204b acts as a protective barrier to preserve the stability and reflectivity of the multilayer structure over time.

A third step of the fabrication process may involve absorber layer deposition 206. An absorber layer 206a may comprise a thin film of tantalum boron nitride (TaBN) or tantalum-based compounds deposited on top of the multilayer stack 204a, which can be used to absorb EUV light where the mask should block light from reaching the wafer. The thickness of the aabsorber layer 206a is typically in the range of 50-70 nm.

A buffer layer 206b may be introduced between the capping layer 204b and the absorber layer 206a for several purposes. Some of those purposes may include: (a) improving mechanical integration between the absorber layer 206a and the multilayer stack 204a; (b) reducing mechanical stress between layers with different material properties; (b) controlling interface properties, such as adhesion and etching selectivity during absorber patterning; (c) helping in etching during the patterning process by improving selectivity between layers; (d) modulating reflectivity at the interface to reduce unwanted reflections (often called optical proximity effects); (d) improving lithographic accuracy and reducing mask 3D effects.

A fourth step of the fabrication process may involve patterning the absorber layer 212. A layer of photoresist 208a is applied to the absorber layer 206a. The patterning of the absorber layer 206a is done using electron beam (e-beam) lithography. The e-beam writes the desired circuit pattern directly into the photoresist layer 208a, defining the areas where the absorber material 206a will remain or be etched away. After e-beam exposure, the photoresist layer is developed to reveal the areas of the absorber layer that will be etched 212a.

A fifth step of the fabrication process may involve absorber etching 214. The pattern is transferred from the resist 208a to the absorber layer 206a. The areas exposed by the developed resist are etched away, leaving a patterned absorber 214a that defines the features of the chip.

A sixth step step of the fabrication process may involve resist stripping and cleaning 216. After the pattern has been etched into the absorber layer, the remaining resist is stripped away 216a, and the mask is cleaned to remove any contaminants or debris.

A seventh step of the fabrication process may involve defect inspection 218 and repair 219. If defects are found, the mask may be repaired using techniques such as focused ion beam (FIB) repair or e-beam repair, which can either add material or remove defects to restore the mask's functionality.

Another step of the fabrication process may include pellicle attachment. EUV masks are highly sensitive to particle contamination. A pellicle (thin transparent membrane) (not shown in FIG. 2) can be placed over the mask surface to protect it from particles during the lithography process, without interfering with the EUV light.

An eight step of the fabrication process may include buffer layer etching 222. Once the absorber is etched, the same or a different etching process may be used to etch through the buffer layer 222a. The choice of etching chemistry and process may depend on the buffer material (e.g., silicon oxide, silicon nitride, etc.). The goal is to etch the buffer layer selectively, without damaging the underlying reflective multilayer stack.

A final step of the fabrication process generally includes final cleaning, inspection, and qualification 224. Once the mask has been cleaned and inspected, it undergoes final testing to ensure that it meets the stringent specifications required fro EUV lithography, including critical dimension (CD) uniformity, reflectivity, and defectivity.

As another example, a circuit schematic targeting a critical dimension at 14 nm may require a DUV (Deep UltraViolet) mask.

The fabrication of EUV masks can be, but is not always, split between two facilities. For example, a first facility may manufacture the EUV blanks. And a second facility may use the EUV blanks and perform the steps needed to create a final mask. Reasons for using more than one facility include differences in technical capabilities and capital-intensive tools.

Because masks are a source of yield loss in the semiconductor device fabrication process, masks are inspected to determine the extent of the defects in the masks. Silicon that is exposed through sections of the mask with defects are not likely to yield working semiconductor devices. In the case of EUV masks, inspections are performed on the EUV blanks and on the final EUV masks to determine the distribution and severity of the defects. The distribution of the defects is completely unique for each mask.

The fabrication process involves using the masks to transfer the circuit patterns onto the semiconductor substrate. This typically involves techniques such as photolithography, etching, doping, and deposition. Semiconductor fabrication facilities, or fabs, use specialized equipment and processes to create the intricate features required for modern semiconductor devices.

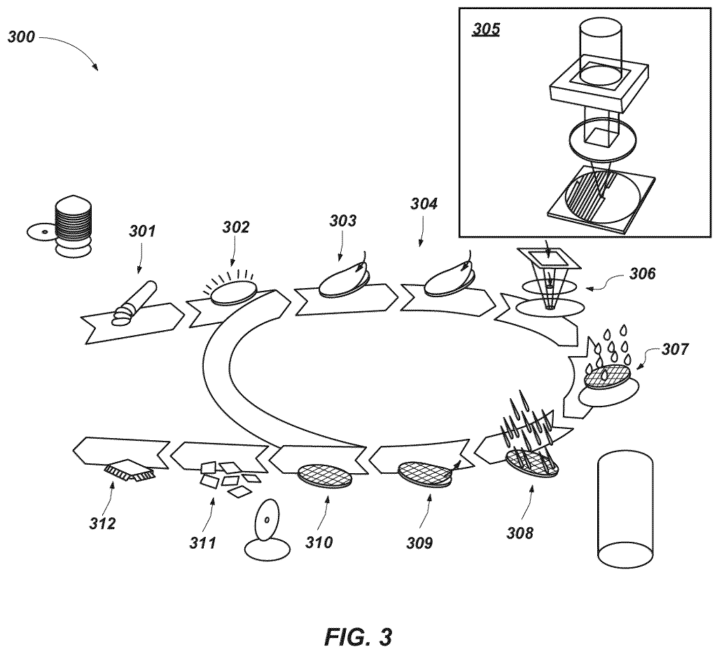

FIG. 3 illustrates an example of a process 300 for fabricating a semiconductor chip, including wafer processing, in accordance with one aspect of the technology. The steps of this process 300 may include: (301) wafers are sawed out of a block (inget) of very purs crystalles silicon; (302) polishing; (303) material deposition or modification; (304) resist application; (305) lithography; (306) exposure; (307) etching; (308) ion implantation; (309) resist removal; (310) final cleaning and inspection; (311) dicing; and (312) packaging.

The primary input to this manufacturing process 300 is a polished wafer. Steps 303 through 310 in FIG. 3 highlight major steps in semiconductor fabrication. Step 305 is the lithographic step. The patterns in the lithography mask produce a result in the silicon wafer. The result could be the deposition of a material that is masked by the lithographic mask. The result could also be the etching of the silicon or previously deposited material in locations defined by the mask.

Each use of a mask in Step 305 (lithographic step) in FIG. 3 has the potential to further damage the mask. Inspecting the mask after use can be done to determine if the mask has been damaged. Any additional damage that a mask incurs through use can be used to update a physically unclonable feature (PUF) associated with the mask; in this manner, the PUF for the mask may evolve with use.

Many semiconductor devices today are fabricated on silicon wafers that are 300 mm in diameter. Many semiconductor devices are also fabricated on silicon wafers that are smaller (e.g., 200 mm in diameter). However, other sizes may also be used (e.g., 50.8 mm, 76.2 mm, 101.6 mm, 150 mm). In all cases, because there are often many semiconductor devices per wafer, the silicon wafers are typically diced. Dicing is the process of cutting the wafer into the individual semiconductor devices or dies. This process is also referred to as singulation.

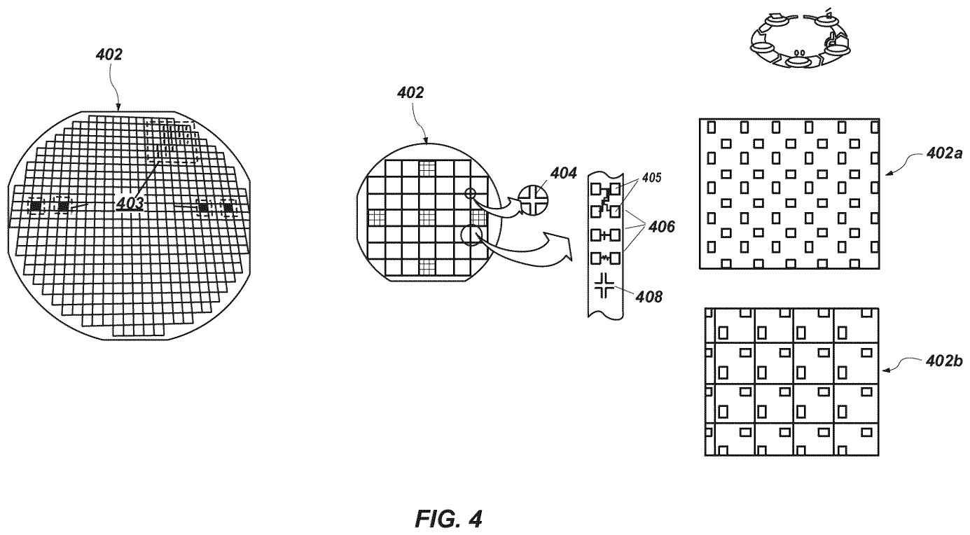

With reference to FIG. 4, a silicon wafer 402 contains many sections that do not have useable dies. These unusable dies 403 may include: (1) dies that have failed earlier testing and have been determined to be un-useable; (2) test dies that are on the wafer for other purposes; and (3) scribe lines 404. Scribe lines 404 are the locations where the wafer 402 will be cut or diced 402a, 402b. Test patterns 406, alignment targets 408, and other features are often placed within the scribe lines 404.

In accordance with one aspect, once the semiconductor devices are fabricated, they are packaged to protect them from environmental factors such as moisture, dust, and mechanical stress. Packaging also provides electrical connections between the semiconductor device and the external circuitry. Packaging can range from simple encapsulation to more complex packaging solutions such as Ball Grid Array (BGA) and Chip-on-Board (COB).

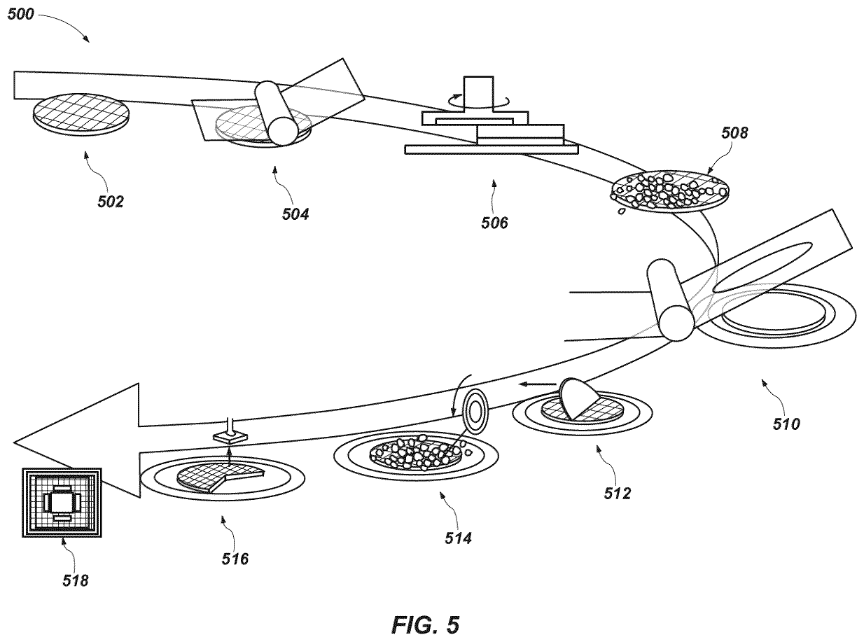

In one aspect of the technology, the input to a semiconductor packaging facility is a patterned or processed wafer. The wafer must be diced or singulated to produce dies that can be mounted in a package to create the final semiconductor device. FIG. 5 shows one example of a process flow 500 for dicing or singulation. In this process flow 500, a front side tape 504 is applied to the patterned or process wafer 502 from the wafer fabrication facility, or wafer fab. This tape 504 is used to protect the patterned wafer 502 during the backgrinding process 506. Backgrinding 506 is done to reduce the thickness of the silicon wafer; this is advantageous for multichip modules that incorporate several dies into one package. After washing 508, a dic attach film 510, or DAF, is applied to the exposed surface of the silicon wafer. The initial front side tape 502 is then removed 512. The DAF 510 helps protect the silicon dies during the dicing operation 514. After dicing, the dies are then removed 516 and placed into the final package 518. In one aspect of the technology, for certain DAF structures, portions of the DAF 510 will stay with the die and can be used to facilitate the packaging process.

After packaging, the semiconductor devices often undergo testing to ensure they meet the specified performance criteria and quality standards. This involves electrical testing, functional testing, reliability testing, and/or environmental testing. Any defects or deviations from the specifications are identified and addressed during this stage.

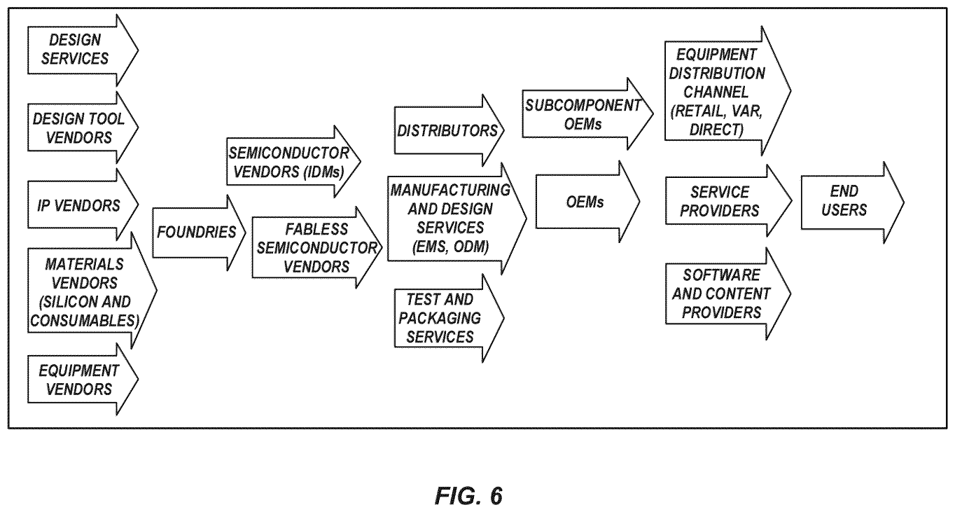

Semiconductor devices contain proprietary information. In order to secure the semiconductor device from inception to disposal, the proprietary information must remain secure throughout the development and manufacturing processes and after insertion into the supply chain. FIG. 6 shows how the proprietary information moves from concept (e.g., vendors, design services, etc.) to fabrication (e.g., foundries, electronic manufacturing services, etc.) to the end user.

Manufacturers of design tools may not fabricate devices. Consequently, there may be multiple layers that require secure, traceable processes to ensure that the proprietary information remains secure.

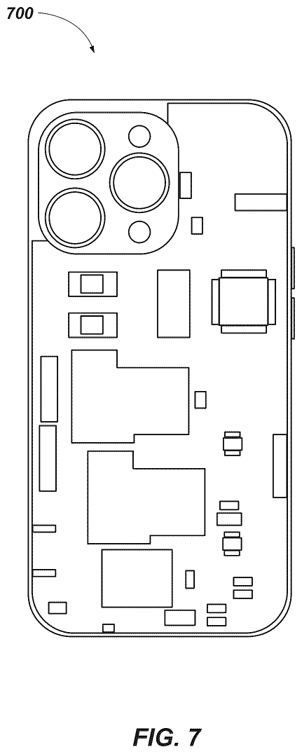

In one aspect, in any final product, multiple semiconductor devices may be used. As an example, a final product 700 is shown in FIG. 7. Failure to track all the semiconductor devices that are incorporated into a final product threatens the proprietary information within the final product.

With the present technology, secure marks may be incorporated at various stages in the lifecycle of a semiconductor device. As non-limiting examples, secure marks may be incorporated into the design process, the mask fabrication process, and the wafer fabrication process.

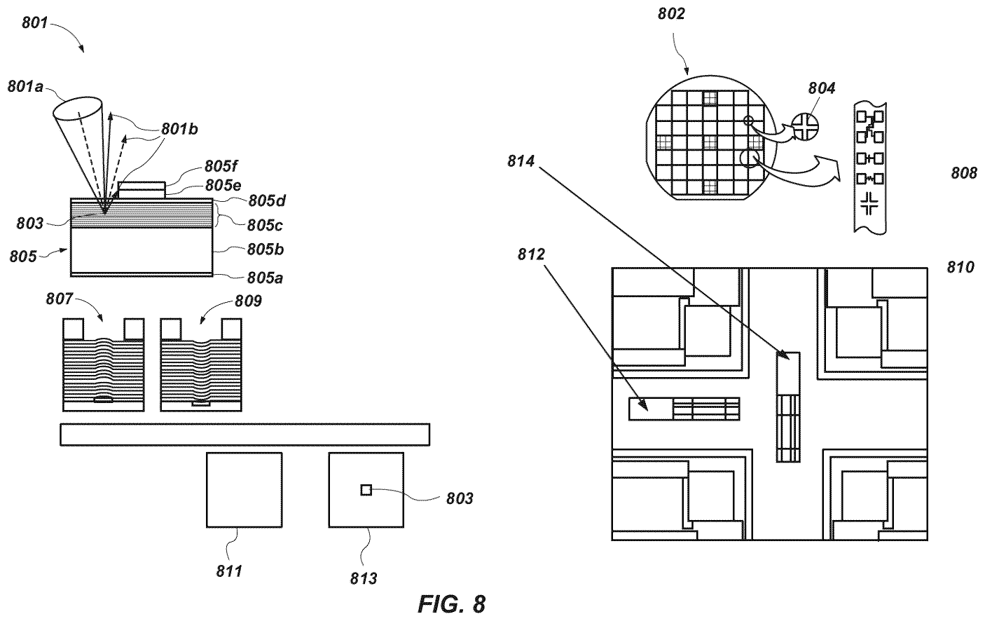

With reference to FIG. 8, in one aspect of the technology, one or more secure marks 812, 814 may be incorporated into the design process as one or more physical marks appearing in the scribe lines 804 on the silicon wafer 802.

Scribe lines 804 on a silicon wafer 802 are narrow grooves or lines that are etched into the surface of the wafer 802. These lines 804 are used as guides for dicing or cutting the wafer 802 into individual semiconductor chips or dies during the manufacturing process.

For the fabrication of semiconductor devices for certain contractors (e.g., a prime contractor), in one aspect of the technology, software data may represent the physical mark provided to a designer 812 (design engineer, design team, or outside design house). Once the design is transmitted from the designer to a mask fabricator, the mask fabricator can confirm that the mark 812 is present. Using a smart contract approach with a blockchain ledger, the transfer of the digital data from the designer to the mask fabricator can be confirmed by the two parties, e.g., the designer and the mask fabricator, and confirmed by the prime contractor. The prime contractor can provide a second digital mark 814 to the mask fabricator to be incorporated into the mask set. As an example, FIG. 8 shows the combination of two secure marks (812, 814) embedded in in the scribe lines 804 on the silicon wafer 802, the mark from the designer 812 and the mark from the mask fabricator 814.

In addition to secure marks that may be added by the designer and the mask fabricator, the intrinsic defects within the wafer itself or within the masks may be used as an additional layer of security. Examples of defects that are intrinsic to the mask set may include chrome deposition nonuniformity, chrome edge roughness, pinholes, etching residue, pellicle defects, phase defects, and phase shift errors. Chrome deposition nonuniformity are inconsistencies in the deposition of chrome material on the mask substrate that can lead to variations in the opacity of the chrome layer. This can result in regions where the pattern is not accurately transferred during lithography. Chrome edge roughness are irregularities in the edges of chrome features on the mask, such as roughness or waviness, that can cause distortion or blurring of the transferred patterns, especially in high-resolution lithography. Pinholes are small holes or voids in the chrome layer of the mask that can allow light to pass through where it should not, causing unintended exposure of the photoresist on the wafer. A pellicle is a thin membrane mounted on top of the mask to protect it from contamination. If a pellicle has defects (e.g., tears or particles) it can lead to defects in the transferred patterns.

Phase defects are imperfections in the photomask used during the photolithography process. Specifically, a phase defect occurs when there is an unintended phase shift in the light passing through the mask, leading to incorrect exposure of the photoresist on the wafer. In photolithography, masks define the patterns of circuits on the semiconductor wafer. Phase defects can arise from contamination, damage, or structure inconsistencies in the maks that cause the light's phase to deviate from its intended behavior. This results in the projected pattern being distorted, leading to faults in the circuits being manufactured, such as shorts, open circuits, or variations in critical dimensions.

A phase shift mask (PSM) is an advanced type of photomask used in photolithography to improve the resolution and image fidelity of semiconductor patterns, especially as feature sizes become smaller. Phase shift masks work by manipulating the phase of light waves, in addition to blocking or transmitting light like a tradition mask. Errors in the phase shift regions can lead to incorrect interference patterns and degradation of pattern fidelity.

As illustrated in FIG. 8, phase defects 803 can be detected using an Extreme Ultraviolet (EUV) source 801a. EUV inspection tools use an EUV light source 801 to identify phase defects 803 by analyzing how the light 801a from the EUV light source 801 interacts with the mask's 805 surface and buried layers. In one aspect of the technology, as shown in FIG. 8, the mask 805 may be scanned with an EUV light source 801. EUV inspection tools detect how the light 801a scatters or reflects 801b off the mask 805. Phase defects 803 can alter the reflection of EUV light 801a, 801b.

More specifically, FIG. 8 shows an EUV mask 805 comprising: a conductive backside coating 805a, a low thermal expansion material (LTEM) 805b, a stack of Molybdenum/Silicon (Mo/Si) multilayers 805c, a capping layer 805d, an absorber layer 805e, and an anti-reflective coating 805f. EUV inspection tools, including an EUV light source 801, are used to detect a phase defect 803 in the Mo/Si multilayers 805c.

Deep Ultraviolet (DUV) light has a wavelength of 193 nm. DUV light is in the shorter part of the ultraviolet spectrum, but it is still longer than EUV light. EUV light is much shorter in wavelength than DUV. EUV light has a wavelength of 13.5 nm. EUV light allows for much finer resolution than DUV light, which is crucial for advanced semiconductor manufacturing, especially sub-7 nm process nodes. The DUV image 811 illustrates that the phase defect 803 is not visible using DUV inspection tools. The EUV image 813, on the other hand, illustrates that the phase defect 803 is visible using EUV inspection tools.

As further illustrated in FIG. 8, the presence of buried bumps 807 and buried pits 809 in the LTEM substrate, intrinsic to the fabrication of EUV masks, creates an random physically unclonable feature (PUF) that can be interrogated using EUV inspection methods. This PUF cannot be recreated in another mask and can only be detected using specific tools.

In one aspect of semiconductor manufacturing, a mask blank is the starting material used to fabricate photomasks, which are essential tools in the lithography process for transferring patterns on the semiconductor wafers. Several defects can potentially occur in the mask blank, including particles, scratches, pits, bubbles, etching residue, and edge defects. Particles on the surface of the mask blank can obstruct the pattern transfer process during lithography, resulting in defects on the semiconductor wafer. These particles may come from the manufacturing environment, handling, or storage environment. Scratches or other forms of surface damage on the mask blank can distort the patterns transferred onto the wafer. Pits are localized areas of material removal or imperfections on the surface of the mask blank. They can interfere with the uniformity of the pattern transfer process. Bubbles trapped within the material of the mask blank can cause variations in the optical properties of the mask, leading to defects in the transferred patterns. Residual material left over from the manufacturing process, such as etching residue, can contaminate the surface of the mask blank and affect the fidelity of the pattern transfer. Also, irregularities or defects along the edges of the mask blank can cause distortions in the transferred patterns, especially in regions close to edge of the mask.

In one aspect of the technology, a method for mapping the defects that are intrinsic to the mask set is disclosed. For example, EUV blanks may have defects that occur at the interface between the LTEM (“Low Thermal Expansion Material”) and the multi-layer mirror (i.e., multi-layer coating). Defects at this interface cannot be added later in the process. In addition, defects at this interface can only be observed using specific measurement tools designed for EUV inspection. Once the final EUV mask has been fabricated, the combination of the defects in the EUV mask blank, which are still present, and the defects associated with the processing of the mask blank create a physically unclonable feature (PUF) that naturally evolves as each mask is used and can be monitored throughout the wafer processing steps.

For example, in one aspect of the technology, the mask defect map is measured before and after each use. The mask defect map is then registered digitally in the blockchain based smart contract system by the wafer processing company using a digital key provided by the prime contractor. This allows the prime contractor to confirm that the correct mask was used at each wafer processing step. The prime contractor can also monitor the degradation of the mask to determine if a replacement mask is needed.

A patterned wafer that enters the packaging process will first be diced into individual dies. During the dicing process, the secure marks for the designer and the mask fabricator will be destroyed. Consequently, absent a secure mark at the die level, there is an opportunity for a malicious actor to insert counterfeit dies in a manner that may otherwise be difficult to detect. To enable detection, one aspect of this technology uses a physically unclonable feature (PUF) or unique secure mark that is attached to individual dies just prior to singulation. For example, incorporation of a secure mark in the die attach film (DAF) tape maintains traceability from the design through the dicing process and packaging process.

In one aspect of the technology, a secure mark is the random dispersion of X-rays, light, electromagnetic radiation, or acoustic scattering particles and/or voids within the DAF tape. When added to the adhesive layer of the DAF tape, these particles and/or voids will not impede the attachment of the die to the final package. The use of particles and/or voids that can effectively scatter either X-rays, electromagnetic radiation, light, or acoustic waves (and, in some cases, two or more) can enable on-going inspection and confirmation from the die in the package upstream through the wafer processing steps and back to the original designer.

In another aspect of the technology, a secure mark is the ordered dispersion of X-rays, light, electromagnetic radiation, or acoustic scattering particles and/or voids within in the DAF tape.

In another aspect of the technology, a secure mark is the pseudo-ordered or pseudo-random dispersion of X-rays, light, electromagnetic radiation, or acoustic scattering particles and/or voids within the DAF tape.

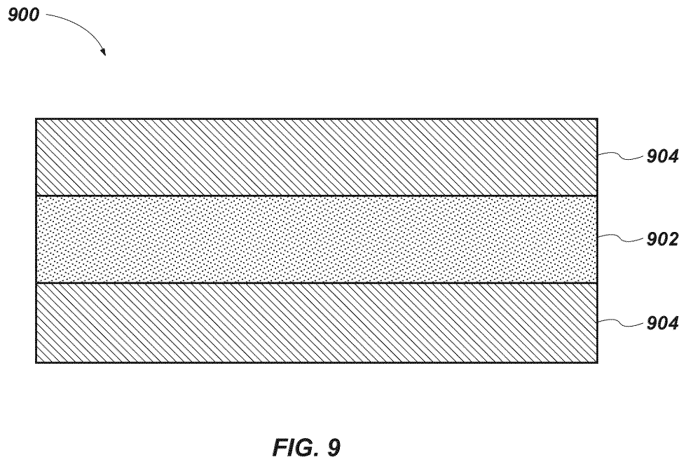

A general structure of a die attach film 900, or DAF, tape is shown in FIG. 9. DAF tape is a thin adhesive film used in semiconductor packaging to attach semiconductor dies to their packages or substrates. It provides a method for mechanically securing the die to the substrate while also providing electrical conductivity or insulation as well as thermal conductivity characteristics. DAF tape is also used to protect the wafer during the dicing process. DAF can comprise several materials. Some example materials, include Low Density Polyethylene (LDPE); High Density Polyethylene (HDPE); Polypropylene (PP); and Polyethylene Terephthalate (PET).

According to one aspect of the technology, specific particles are dispersed either in one or more of a base layer, an adhesive layer 902, or a release liner 904 of the DAF tape to create a unique security mark. Because the release liner does not remain an integral part of the package, the particles dispersed in the release liner can be chosen from any material. However, because a release liner will be removed during packaging, this approach does not create a permanent security mark.

In accordance with one aspect of the technology, specific materials are dispersed in the adhesive layer 902 of the DAF tape 900. In one aspect, materials dispersed in the DAF tape 900 meet at least the following criteria: (1) the materials do not interfere with adhesion to either the semiconductor die or the package (or other die in the case of die-to-die packaging); (2) the materials do not degrade the thermal properties of the adhesive layer; and (3) the materials do not create electrical shorts that could cause device failures.

Proper selection of materials for dispersing in the adhesive layer 902 has the advantage of creating a secure mark that remains with the die even after packaging. Some examples of suitable particles include metal, glass, and/or ceramic particles.

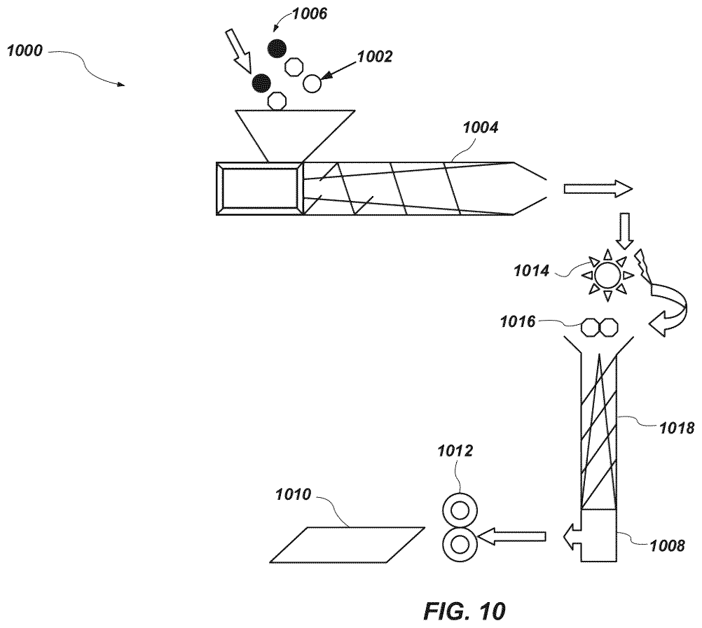

In one aspect of the technology, with reference to FIG. 10, die attach films are manufactured using an extrusion process 1000. Extrusion is a method for producing continuous lengths of plastic or polymer films with a consistent thickness and width. The process starts with the preparation of raw materials 1002, which can include, by way of example, thermoplastic polymers such as polyimide (PI) or polyethylene terephthalate (PET). These polymers 1002 may be supplied in the form of pellets or granules. The raw materials 1002 are fed into an extruder 1004, which is a machine equipped with a screw mechanism. Inside the extruder 1004, the raw materials 1002 are heated to a controlled temperature, causing them to melt and mix together uniformly. Any additives or fillers, such as thermal conductive fillers may be introduced into the melt at this stage. In one aspect of this technology particles 1006 (e.g., metal, glass, or ceramic particles) may also be added at this stage thereby creating a random distribution of particles in the resultant film.

The molten polymer mixture is then forced through a cast film die 1008, which is a specially shaped opening or nozzle (and not to be confused with a semiconductor die or chip). As the polymer passes through the cast film die, it is shaped into a continuous thin film with a uniform thickness and width 1010. After exiting the cast film die, the extruded film is rapidly cooled using air or water to solidify the polymer material and maintain its desired shape. The cooling process involves passing the film through a series of rollers or a cooling chamber to ensure uniform cooling and minimize distortion. The resulting film 1010 can be used a release liner or may be further processed and coated with adhesive layers, thermal conductive fillers, and other additives to create a finished DAF tape product.

In one aspect of the technology, an extruded blend from a first mixing extruder 1004 may be pelletized 1014. Granules of a polymer alloy blend 1016 may be fed into a second extruder 1018 and forced through the cast film die 1008. In one aspect of the technology, particles 1006 may be added to the granules of the polymer alloy blend 1016 before being fed into the second extruder 1018 and forced through the cast film die 1008.

Adding particles to the adhesion layer can be more complicated than adding particles to the release liner. The adhesion layer in a DAF may be manufactured with a base film and an adhesive material. Base films, such as polyimide, LDPE, HDPE, or PET, are manufactured as described above without the addition of particles. The adhesive layer is then coated onto the base film.

Adding particles to the adhesion layer can be done using any of the following methods: (1) mixing the particle with the base film material during the extrusion of the base film, as described above; (2) coating the particles directly onto the base film; (3) mixing the particles with the adhesion material and then coating the mixture onto the base film; and (4) depositing the particles onto the base film in a vacuum environment (i.e., vacuum deposition). All of the above methods can be used to create a random, ordered, pseudo-random, and/or pseudo-random distribution of particles.

In another aspect of the technology, with reference to FIG. 10, an ordered distribution of particles and/or voids can be added during the extrusion process. For example, an ordered pattern can be printed onto the film at the drawing unit 1012.

One aspect of this technology is imaging or mapping a unique dispersion of particles and/or voids (i.e., a security mark) that have been randomly added to a DAF tape structure. DAF-S tape (where “S” stands for “security”) means DAF tape that includes one or more security marks or a unique random or ordered dispersion of particles that can be imaged and/or mapped.

The following are examples of particles that could be used in accordance with the technology: (1) metal particles, which will scatter light, sound, and x-rays; (2) glass particles will scatter light and sound; and (3) ceramic particles will scatter light, sound, and x-rays. In one aspect of the technology the particles could comprise any material that can be randomly dispersed in the DAF tape and are detectable by an imaging device.

The following are examples of detection methods that could be used to detect the presence of particles in the DAF-S tape: (1) optical imaging for particles that scatter light; (2) X-ray imaging for particles that scatter X-rays; (3) phase array ultrasonic imaging for particles that scatter sound waves; and (4) total focusing method (TFM) ultrasonic imaging for particles that scatter sound waves.

Some examples of optical imaging devices that could be used to detect particles that scatter light include optical microscopes (e.g., brightfield, darkfield, phase contrast, and differential interference contrast (DIC) microscopes); scanning electron microscopes (SEMs); transmission electron microscopes (TEMs); focused ion beam (FIB) systems; atomic force microscopes (AFMs); confocal microscopes; X-ray microscopes; infrared microscopes; scanning probe microscopes (SPMs); critical dimension scanning electron microscopes (CD-SEMs); and photoacoustic microscopes).

In one aspect of the technology, the imaging or mapping of the unique dispersion of particles and/or voids includes generating a three-dimensional (3D) volume-rendered image or map.

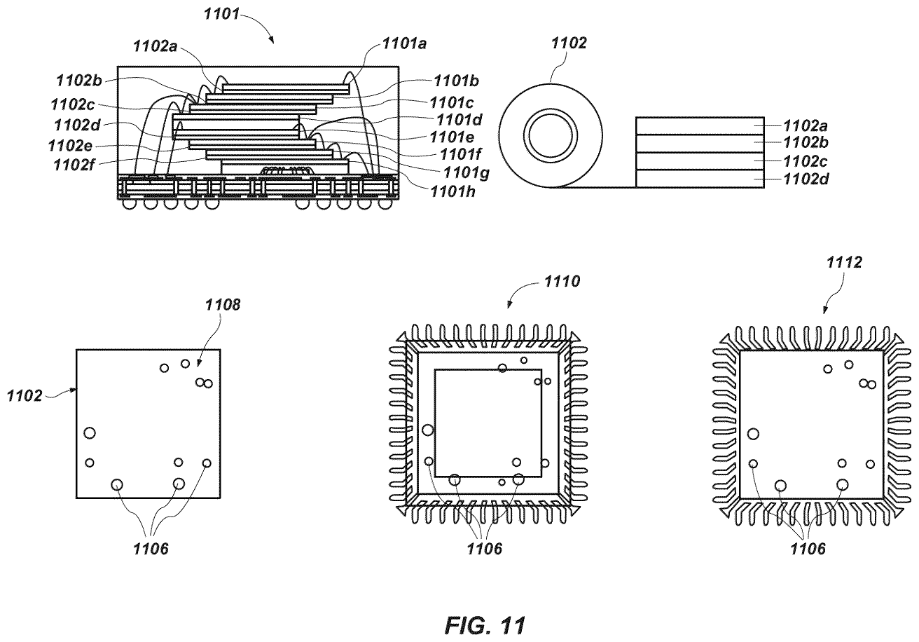

FIG. 11 shows an example of a random dispersion 1108 of particles 1106 in a die attach film (DAF) 1102. FIG. 11 shows a die attach film (DAF) 1102 comprising a cover film 1102a, an electroconductive film 1102b, an adhesive layer 1102c, and a base film 1102d. The DAF may be randomly embedded with a random distribution 1108 of particles 1106. The random distribution 1108 may be detectable after the die attach process using X-ray, Total Focusing Method (TFM), or other imaging means 1110. The random distribution 1108 may then be identified. In other aspects of the technology, the random distribution 1108 may be a pseudo-random distribution, an ordered distribution, or a pseudo-ordered distribution.

FIG. 11 further shows a stack 1101 of semiconductor dies 1101a-h. Between the semiconductor dies 1101a-h are die attach films 1102a-f. In one aspect of the technology the random dispersion 1108 of particles 1106 in a die attach film may comprise a random dispersion 1108 of particles 1106 in two or more layers of die attach films 1102-f in a stack 1101 of two or more semiconductor dies 1101a-h.

For situations where the DAF-S can be directly imaged (e.g., after attaching the DAF-S to the wafer, after singulation, and prior to packaging), optical, acoustic, and X-ray imaging is straightforward. Once the die is packaged, the imaging method used depends on the impact of the package material. For example, in one aspect, it is believed that aluminum oxide particles have an acoustic impedance of approximately 39.7M kg/m²s. This is more than ten times higher than plastic. Consequently, it is believed that using phase-array or TFM on a plastic package that has a die with a DAF-S that has aluminum oxide particles should yield good contrast. In one aspect of this technology, TFM using a 5 MHz transducer can penetrate a plastic package scatter off of aluminum oxide particles dispersed within DAF tape.

As non-limiting examples, DAF-S tape can be imaged during any of the following steps: (1) prior to attachment of the DAF-S tape to a wafer; (2) while the DAF-S tape is attached to a wafer; (3) after dicing of a wafer (only the portion of the DAF-S tape that is on the die can be imaged) but prior to removal of the final release liner of the DAF-S tape; (4) after removal of the final release liner of the DAF-S tape (and only if the particles are located in the adhesive layer of the DAF-S tape); (5) after adhesion of the DAF-S tape to other die or the package (only if the particles are located in the adhesive layer of the DAF-S tape); and (6) after packaging is complete (only if the particles are located in the adhesive layer of the DAF-S tape and if the particles enable non-contact, non-destructive imaging methods).

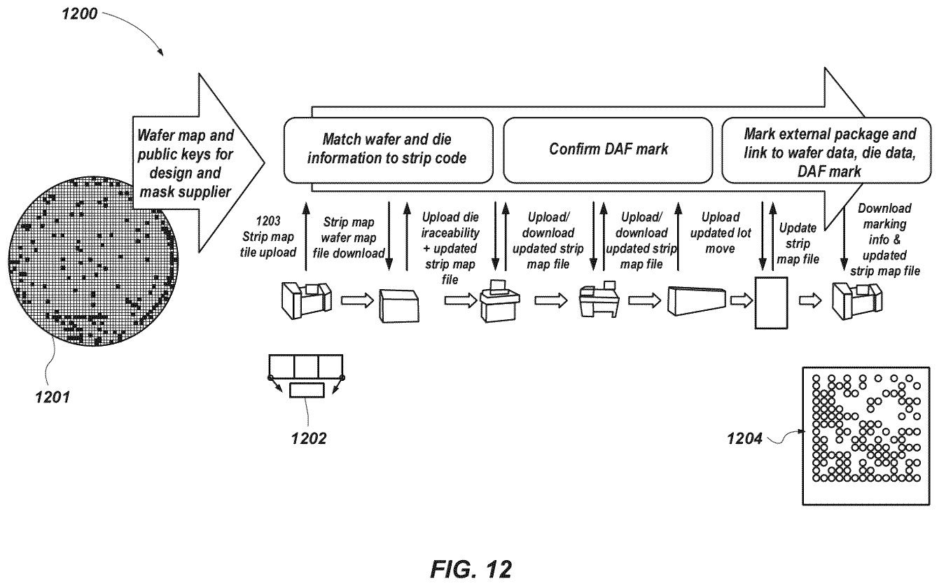

Once the DAF-S tape is attached to the wafer, the entire wafer is imaged using an appropriate non-destructive testing method (e.g., X-ray, acoustic waves, electromagnetic radiation) to determine the spatial arrangement of particles with respect to each die in the wafer map. After the dicing step, the DAF-S tape attached to the die can be imaged to confirm that the die has the expected spatial arrangement of particles when compared to the pre-dicing image. With appropriate non-destructive testing methods, dice can be imaged even when inside a package. Multi-chip modules with stacked dice can also be imaged to confirm that all the individual die inside a package can be traced upstream through wafer processing back to the original design. The substrate onto which the die is mounted and bonded can also have a secure mark. This may help ensure the integrity of the packaged dic through the die attach process. This can be generalized to other approaches with similar characteristics. The combination of multiple security marks that are connected to specific components and process steps can create a unique and evolving security system that can quickly detect security breaches from fraudulent processing. Once the die has been marked with a secure mark and packaged into a semiconductor device, an external mark can also be applied to the surface of the packaging, which can enable continued tracking downstream. FIG. 12 shows an example of how multiple secure marks can be applied and maintained throughout the packaging process.

In one aspect of the technology, the wafer map 1201 can be a secure mark. In another aspect of the technology, a substrate strip code 1202 onto which a die is placed can be a secure mark. A strip map 1203 may comprise one or more strip codes 1202. In one aspect of the technology, the wafer map 1201 and the strip map 1203 may be used to match wafer and die information. A DAF mark can be linked to the wafer map 1201 and strip map 1203. And an external package mark 1204 can be linked to the DAF mark, which is linked to the wafer map 1201 and strip map 1203.

In some embodiments, the secure mark may be a three-dimensional (3D) mark. 3D marks are more robust to downstream manufacturing processes and varying environmental conditions. Throughout the packaging process, the combination of the secure marks associated with the die and with the substrate can be measured physically with the appropriate non-destructive testing (NDT) methods. For example, the die secure mark may be monitored using acoustic imaging methods (e.g., phased array ultrasonics, TFM (total focusing method) ultrasonics, or X-ray). The substrate secure mark may be monitored using 3D imaging. In one embodiment, the 3D secure mark can be encoded (e.g., via 256 AES encryption). Once the final package cover is placed, an external mark 1204 can be placed on the package. In one embodiment, this secure mark 1204 is a 3D mark.

The final product mark provides a chain of custody for all of the security marks associated with the components in the final product. For example, the secure marks of the packaged semiconductor devices that are part of a circuit board assembly can be associated in a database to the secure mark of the circuit board assembly. This is similar to the way in which a multilevel bill of materials (BOM) is used to identify the connections between components, subassemblies, and the finished product or final assembly.

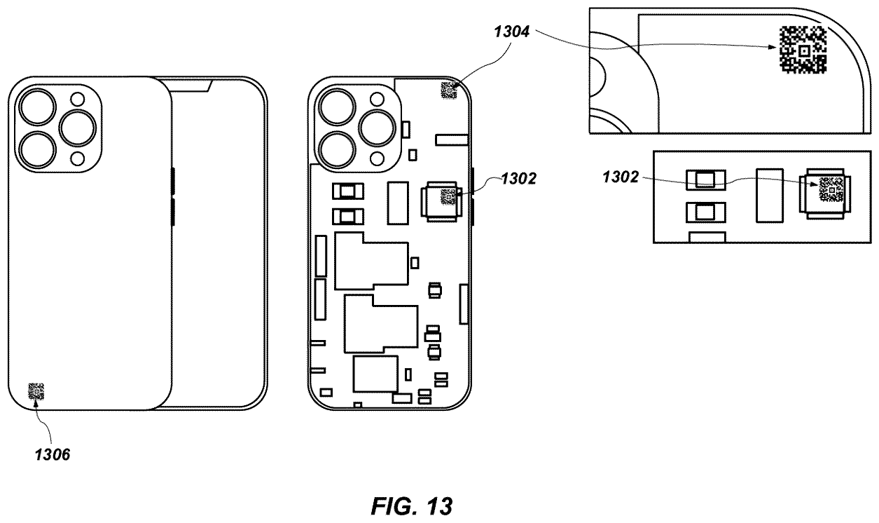

The final product, or component, now has a multi-factor means of authentication. For example, as a first means of authentication, the external package mark 1302 created on the packaging surface during final packaging of the semiconductor device (see FIG. 13) contains a unique code that links to the database, which shows the lifecycle and chain of custody of the component. A circuit board may include a circuit board mark 1304. And the final product may include an external product mark 1306. The external package mark 1302, the circuit board mark 1304, and the external product mark 1306 may be the same external surface mark. In another aspect of the technology, the external package mark 1302, the circuit board mark 1304, and the external product mark 1306 may be different marks but will be linked together in a database.

As the component continues to be transferred throughout the various steps and multitude of individual participants in the manufacturing process, each scan of the component updates the chain of custody in the database. And the internal package mark (e.g., DAF-S mark), provides a second means of authentication that can be verified using appropriate non-destructive testing.

In one embodiment, the external surface mark (1302, 1304, 1306) prevents components from being vulnerable to some forms of counterfeiting. For example, “blacktopping” is where counterfeiters sand down and resurface parts to remove old markings. However, “blacktopping” will destroy the 3D elements of the mark and thus it will not appear in the database. And remarking to change the part number will also not match up to the records in the database. Creating a false mark will not appear in the database. A recycled part that was previously disposed will also be flagged as counterfeit or ineligible for re-use. If a surface mark or other questions as to the authenticity of the component arise, then the multiple layers of DAF can be analyzed and compared to the history and the surface marking. All the manufacturing steps are built sequentially within the database, and any substitution or alteration of a marking will fail under the analysis. This sequentially built database may also prevent the substitution of a valid, marked metal component “lid” used in many IC assemblies from being transferred to a substitute die set and passing analysis.

For subassemblies with multiple, secure semiconductors, the spatial arrangement of the devices on a printed circuit board assembly creates an additional PUF specifically associated with the spatial arrangements that can be tracked and used to validate the subassembly.

One goal of this technology is to evolve the process of each supplier providing a CoC (Certificate of Conformance) to the next supplier or service provider. An aspect of this technology creates a secure means of physical validation of each component, or assembly of components (Top or Next level assembly) in a digital manner, tied directly to each individual product. A standard, paper based CoC simply groups a bulk of material together and has no direct connection to anything on an individual basis. The prior art systems rely solely on the integrity of each supplier, e.g., certified as “to the best of my knowledge,” and provide no means of identifying a potential fraudulent substitution individually or in bulk.

The table shown below summarizes various security marks that may be applied at various steps within the lifecycle of a semiconductor device.

| Device | Security | | | How is this | | |
|---|---|---|---|---|---|---|
| Mark | Level | Digital | Physical | measured | Links | Comment |
| DC | ID | Design code | Feature on mask | KLA or Lasertec | Connects Design to Mask | |
| WMC | PUF-Mask | Wafer mask code | Feature on mask | KLA or Lasertec | Connects Mask to Wafer | |
| WC | PUF-Wafer | Design and wafer | Feature on the | KLA | Connect Wafer to Dicing | Marks destroyed at |
| | | mask codes | wafer | | | wafer dicing |
| DAFC | PUF-Device | DAF code | bonded to wafer | TFM or X-ray | Connect Wafer to Die | |
| SC | UUID | Substrate code | 3D etched into | 3D camera | Connect Die to | |
| | | | substrate | | Substrate | |
| PSC | quasi-PUF | Packaged | 3D etched into | 3D camera | Connects Substrate & | DAF and substrate |
| | | Semiconductor | substrate | | Die to packaged | marks no longer |
| | | code | | | seminconductor device | visible after final |
| | | | | | | packaging |
| ShC | UUID | JDEC (or other) | QR code | Camera | Connects shipping | |
| | | shipping code | | | tray/package to all | |
| | | | | | individual components | |

Various device marks may include: design code (DC), wafer mask code (WMC), wafer code (WC), DAF code (DAFC), substrate code (SC), packaged semiconductor code (PSC), and shipping code (ShC). The various device marks may comprise identifiers (ID), physically inclinable features (PUF), quasi-PUF, and universally unique identifiers (UUID).

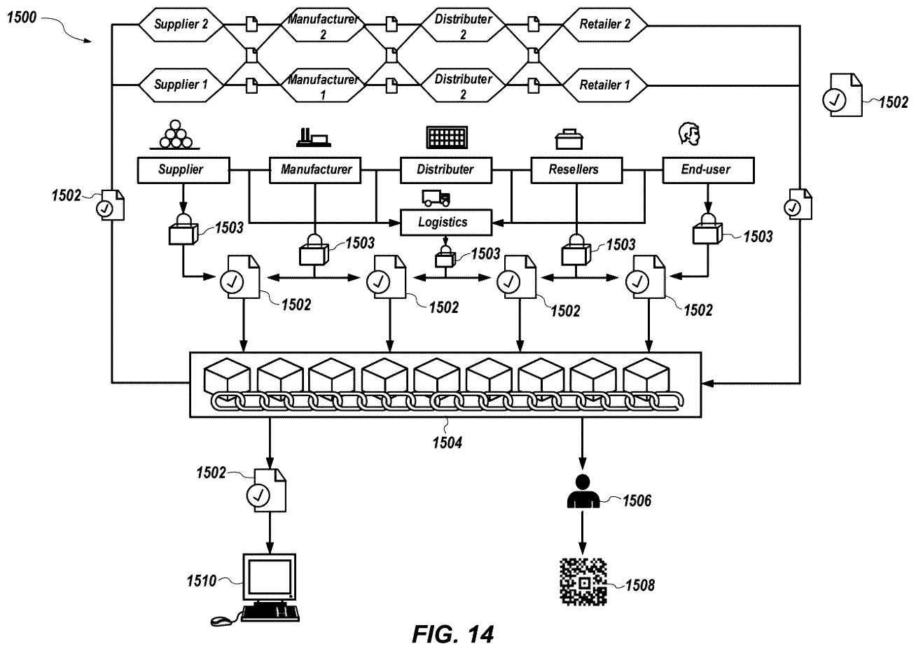

FIG. 14 shows an example of how a series of Smart Contracts 1502 connected to a Blockchain Server 1504 may be used to create a digital record for each transaction. For example, when semiconductor masks are used at the semiconductor fab to process the wafer, the physical verification of the wafer, based, for example, on imaging information from a KLA wafer inspection tool, can be registered as a transaction in the blockchain ledger. Throughout the entire manufacturing process through delivery to the end user 1506, physical information obtained through specific measurements of the secure marks 1508 is linked to specific transactions and can be verified through examination of the blockchain ledger.

In accordance with aspects of this technology, components of this blockchain approach may include various security features 1503, which may include: (1) use of a private (consortium based) blockchain ledger; (2) use of public and private keys to ensure that only participants in the private consortium can participate in the entry and access of data to and from the blockchain ledger; (3) separation of private keys into two components to create a multi-factor authentication process; (4) use of single-use private keys for writing data to the blockchain ledger; (5) use of hardware key lockers to generate and store keys; (6) use of AES 256-bit encryption to secure keys; (7) use of hash functions to secure ledger entries; and (8) implementation of a centralized authority to manage the distribution of keys and access to ledger data.

In accordance with aspects of the technology, components of the secure marks may include: (1) use of extrinsic and intrinsic marks individually or in combination to create physically unclonable features (PUFs) at various stages of conception, fabrication, integration, use, and disposal of semiconductor devices; (2) use of evolving secure marks that change as a function of specific steps; for example, a secure mark that changes because of a semiconductor fabrication step and that indicates that the step was performed securely and as expected; (3) use of multiple measurement modalities to interrogate all aspects of the secure features of a semiconductor device; for example, the following modalities could be used to determine the security and traceability of a semiconductor device; (4) 3D imaging to interrogate the external mark on the device package; (5) x-ray or acoustic imaging to interrogate the individual marks on the die and substrate that are inside the package; and (6) use of the spatial arrangement of multiple secure semiconductor devices to create an additional PUF related to the spatial arrangement of these semiconductor devices.

The foregoing detailed description describes the technology with reference to specific exemplary aspects. However, it will be appreciated that various modifications and changes can be made without departing from the scope of the present technology as set forth in the appended claims. The detailed description and accompanying drawings are to be regarded as merely illustrative, rather than as restrictive, and all such modifications, combination of features, or changes, if any, are intended to fall within the scope of the present technology as described and set forth herein. In addition, while specific features are shown or described as used in connection with particular aspects of the technology, it is understood that different features may be combined and used with different aspects. Likewise, numerous features from various aspects of the technology described herein may be combined in any number of variations as suits a particular purpose.

More specifically, while illustrative exemplary aspects of the technology have been described herein, the present technology is not limited to these aspects, but includes any and all aspects having modifications, omissions, combinations (e.g., of aspects across various embodiments), adaptations and/or alterations as would be appreciated by those in the art based on the foregoing detailed description. The limitations in the claims are to be interpreted broadly based on the language employed in the claims and not limited to examples described in the foregoing detailed description or during the prosecution of the application, which examples are to be construed as non-exclusive. For example, in the present disclosure, the term “preferably” is non-exclusive where it is intended to mean “preferably, but not limited to.” Any steps recited in any method or process claims may be executed in any order and are not limited to the order presented in the claims. Means-plus-function or step-plus-function limitations will only be employed where for a specific claim limitation all of the following conditions are present in that limitation: a) “means for” or “step for” is expressly recited; and b) a corresponding function is expressly recited. The structure, material or acts that support the means-plus-function are expressly recited in the description herein. Accordingly, the scope of the technology should be determined solely by the appended claims and their legal equivalents, rather than by the descriptions and examples given above.

1. A semiconductor die with a unique identifier, comprising:
a semiconductor die;
a die attach film (DAF) comprising a distribution of particles disposed about a surface of the semiconductor die;
wherein the distribution of particles is mapped to the semiconductor die.

2. The semiconductor die of claim 1, wherein the distribution of particles comprises a random distribution of particles.

3. The semiconductor die of claim 1, wherein the distribution of particles comprises an ordered distribution of particles.

4. The semiconductor die of claim 1, wherein the distribution of particles comprises a random distribution of particles and an ordered distribution of particles.

5. The semiconductor die of claim 1, wherein the particles comprise one or more of metal, glass, or ceramic particles.

6. The semiconductor die of claim 1, wherein the die attach film comprises a low density polyethylene (LDPE), high density polyethylene (HDPE), polypropylene (PP), and polyethylene terephthalate (PET).

7. The semiconductor die of claim 1, wherein the die attach film comprises one or more of a base layer, an adhesive layer, and a release liner.

8. The semiconductor die of claim 1, wherein the distribution of particles is imaged using one or more of: X-rays, light, electromagnetic radiation, and acoustic waves.

9. The semiconductor die of claim 1, wherein the distribution of particles is imaged after packaging of the semiconductor die.

10. A film with a unique identifier configured to be disposed about a semiconductor die, comprising:
a planar film;
a distribution of particles or voids disposed about the film;
wherein the distribution of particles or voids is capable of being identified without destroying the semiconductor die.

11. The film of claim 10, wherein the distribution of particles or voids comprises a random distribution of particles or voids.

12. The film of claim 10, wherein the distribution of particles or voids comprises an ordered distribution of particles or voids.

13. The film of claim 10, wherein the distribution of particles comprises a random distribution of particles or voids and an ordered distribution of particles or voids.

14. The film of claim 10, wherein the film comprises a low density polyethylene (LDPE), high density polyethylene (HDPE), polypropylene (PP), or polyethylene terephthalate (PET).

15. The film of claim 10, wherein the film comprises one or more of a base layer, an adhesive layer, and a release layer.

16. The film of claim 10, wherein the particles comprise one or more of metal, glass, or ceramic particles.

17. The film of claim 10, wherein the distribution of particles can be identified using one or more of: X-rays, light, electromagnetic radiation, and acoustic waves.

18. The film of claim 10, wherein the distribution of particles is capable of being identified prior to attachment of the film to the semiconductor die.

19. The film of claim 10, wherein the distribution of particles is capable of being identified while the film is attached to the semiconductor die.

20. The film of claim 10, wherein the distribution of particles is capable of being identified prior to removal of a release layer of the film.

21.-72. (canceled)
